(19) United States
(12) Patent Application Publication
(10) Pub. No.: US 2013/0069157 A1
(43) Pub. Date: Mar. 21, 2013

(54) SEMICONDUCTOR CHIP INTEGRATING HIGH AND LOW VOLTAGE DEVICES

(71) Applicant: Hideaki Tsuchiko, San Jose, CA (US)

(72) Inventor: Hideaki Tsuchiko, San Jose, CA (US)

(73) Assignee: Alpha and Omega Semiconductor Incorporated

(21) Appl. No.: 13/539,360

(22) Filed: Jun. 30, 2012

Related U.S. Application Data
(63) Continuation-in-part of application No. 13/237,842, filed on Sep. 20, 2011.
Application No. 13/237,842 is a continuation-in-part of application No. 13/237,852, filed on Sep. 20, 2011.

(51) Int. Cl. H01L 27/088; H01L 27/08; H01L 27/082

(52) U.S. Cl. 257/337; 257/500; 257/E27.051; 257/E27.053; 257/E27.06

(57) ABSTRACT

The present invention is directed to a semiconductor chip comprising a high voltage device and a low voltage device disposed thereon. The chip may be formed in several different configurations. For example, the semiconductor chip may include a NPN bipolar transistor, PNP bipolar transistor, a diode, an N channel DMOS transistor and the like. The first doped well being configured as a base of the DMOS transistor, a P channel DMOS transistor and the like.

### CROSS REFERENCE TO RELATED APPLICATIONS

This application is a Continuation-in-Part (CIP) of commonly owned pending US application entitled “METHOD OF INTEGRATING HIGH VOLTAGE DEVICES”, by Hideaki Tsuchiko with application Ser. No. 13/237,842, filing date Sep. 20, 2011 and commonly owned pending US application entitled “SEMICONDUCTOR CHIP INTEGRATING HIGH AND LOW VOLTAGE DEVICES”, by Hideaki Tsuchiko with application Ser. No. 13/237,852, filing date Sep. 20, 2011.

Whose content is herein incorporated by reference for any and all purposes.

### BACKGROUND OF THE INVENTION

The invention relates to high voltage semiconductor devices and the manufacturing process thereof and, in particular, to modular techniques for adding high voltage devices to an existing process flow for semiconductor devices.

Devices having higher voltage rating than existing devices are often required to be integrated on a chip of existing device to satisfy the demand of new applications. In many cases such integration of higher voltage device into existing lower voltage device requires drastic change to the proven process flow and/or conditions for manufacturing the existing lower voltage device resulting in performance deterioration of the existing lower voltage device to a degree that device models will have to be updated. To avoid the long design cycle and high cost of new technology development, efforts have been focused on techniques that require only minor changes to the existing low voltage device process conditions thus minimizing the impact to the performance of existing lower voltage device.

Generally in BCD (Bipolar CMOS DMOS) or BiCMOS (Bipolar CMOS) technologies, the highest operating voltage is limited by reach-through breakdown of a vertical structure of P to N junction. This vertical junction breakdown is a function of Epi thickness, doping concentration and junction depth. FIG. 1A shows an example of an existing vertical NPN transistor (VNPN) (N+ emitter and P+ base pickup not shown) device 300 formed in a semiconductor chip comprising a P substrate 14. The device 300 is formed with a non-Epi process, i.e., the device is formed directly in the P substrate 14 without growing an epitaxial layer atop of the P substrate. Therefore, a lightly doped and deep N well is formed at a top portion of the P substrate firstly, in which different device structures, for example VNPN transistors, as shown in FIG. 1A, are formed. Without showing the detail structure of the device 300, a lightly doped and deep N well 35 is formed at a top portion of the P substrate 14. A number of N-wells 22 and a P-well 26 are formed at the top portion of the deep N well 35 forming the VNPN device structure 20. P well 48 is formed at the top portion of the P substrate surrounding the deep N type well 35, thus, providing isolation ring of the device 300 from the rest area of the semiconductor chip where other devices may be formed.

FIG. 1B shows an example of another existing vertical NPN transistor (VNPN) (N+ emitter and P+ base pickup not shown) device 301 formed in a semiconductor chip comprising a P substrate 14. The structure of the device 301 is similar to that of the device 300 as described above in FIG. 1A, excepting that the device 301 optionally comprises an N buried layer 37 formed at the bottom of the deep N well 35, under and adjacent to the P-well 26. In this case, the N buried layer 37 prevents punch through between P-well 26 and P substrate 14 which increases the maximum operating voltage of the device 301. The depth 45 of P-well 26 is controlled to optimize the performance of device 301. However, the bottom of P-well 26 is adjacent to the top of buried N layer 37, thus limits a vertical breakdown voltage therefore limit the operating voltage of device 301.

The manufacturing process of the device 300 would start with the P substrate material 14 then N type dopants is lightly doped to form a deep N well 35 at a top portion of the P substrate 14. Optionally, the N buried layer 37 of the device 301 is formed by a high energy and high concentration of N-type dopant implantation at the bottom of the deep N well 35. Then, multiple N-wells and P-wells are formed in the deep N well 35 extending downward from the top surface of the substrate to form a specific function such as a bipolar transistor or a MOSFET. In the case a higher operating voltage device is required to be integrated in a separate area on the same substrate, it may require a drastic changes to process flow and/or the condition of making the device 300. This will affect the performance and isolation of existing device 300 if the process and condition of making device 300 remain the same.

Another method is introducing a lighter doping layer to reduce the doping concentration and shallow P well junction. For example, Hideaki Tsuchiko discloses in patent application 7019377 an integrated circuit includes a high voltage Schottky barrier diode and a low voltage device. The Schottky barrier diode includes a lightly doped and shallow p-well as a guard ring while the low voltage devices are built using standard, more highly doped and deeper p-wells. By using a process including lightly doped and shallow p-wells and increased thickness of N-Epi, the reach-through breakdown voltage, hence, maximum operating voltage of high voltage devices can be improved. Each method can improve breakdown voltage by 15V to 30V. The Schottky barrier diode using both methods can improve its breakdown voltage 30V to 60V without significantly affecting performance of other devices and structures.

Combination of both methods and device layout enable integrating high and low voltage devices on the same chip. However, these methods often have a minor affect to existing device performances. Some devices require a minor tweak to SPICE models. Therefore it is highly desirable to develop new techniques to integrate a high voltage device into a low voltage chip that require only inserting a few steps to existing low voltage process flow without impacting the performance of the low voltage device.

### SUMMARY OF THE INVENTION

The present invention is directed to a method for forming multiple active components, such as bipolar transistors, MOSFETs, diodes, etc., on a semiconductor substrate so that active components with higher operating voltage may be formed on a common substrate with a lower operating voltage active components and incorporating the existing proven process flow of making the lower operating voltage active components.

The present invention is further directed to a method for forming a device of increased operating voltage over an existing device by adding a few steps in the early manufacturing process of the existing device therefore without affecting the device performance. Specifically the method including the steps of providing a substrate material of a first conductivity type; forming a deep buried region of the second conductivity that includes a lightly doped region and a highly doped region surrounded by the lightly doped region on the top portions of the substrate for the high voltage device; growing an epitaxial layer of the first conductivity type on top of the substrate; forming lightly doped and deep well of the second conductivity type in the top portion of the epitaxial layer ; and forming high voltage and low voltage devices.

These and other embodiments are described in further detail below.

### BRIEF DESCRIPTION OF THE DRAWINGS

FIGS. 1A and 1B are cross-sectional views of an existing device fabricated on a substrate with a non-Epi process.

FIG. 2 is a cross-sectional view of a higher operating voltage device fabricated on a common substrate with a lower operating voltage device of FIG. 1A in accordance with one aspect of the present invention;

FIG. 3 is a flow diagram showing a method of fabricating the structure shown in FIG. 2;

FIGS. 4-8 show cross-sectional views of the active devices shown in FIG. 2 at different steps of the fabrication process shown in FIG. 3.

FIG. 9 is a cross-sectional view of a higher operating voltage vertical NPN bipolar transistor according to the present invention;

FIG. 10 is a cross-sectional view of a higher operating voltage lateral PNP bipolar transistor according to the present invention;

FIG. 11 is a cross-sectional view of a higher operating voltage PN diode according to the present invention;

FIG. 12 is a cross-sectional view of a higher operating voltage lateral N-channel DMOS according to the present invention;

FIG. 13 is a cross-sectional view of a higher operating voltage lateral P-channel DMOS according to the present invention; and

FIG. 14 is a cross-sectional view of a higher operating voltage lateral N-channel DMOS with triple RESURF according to the present invention.

### DETAILED DESCRIPTION OF THE INVENTION

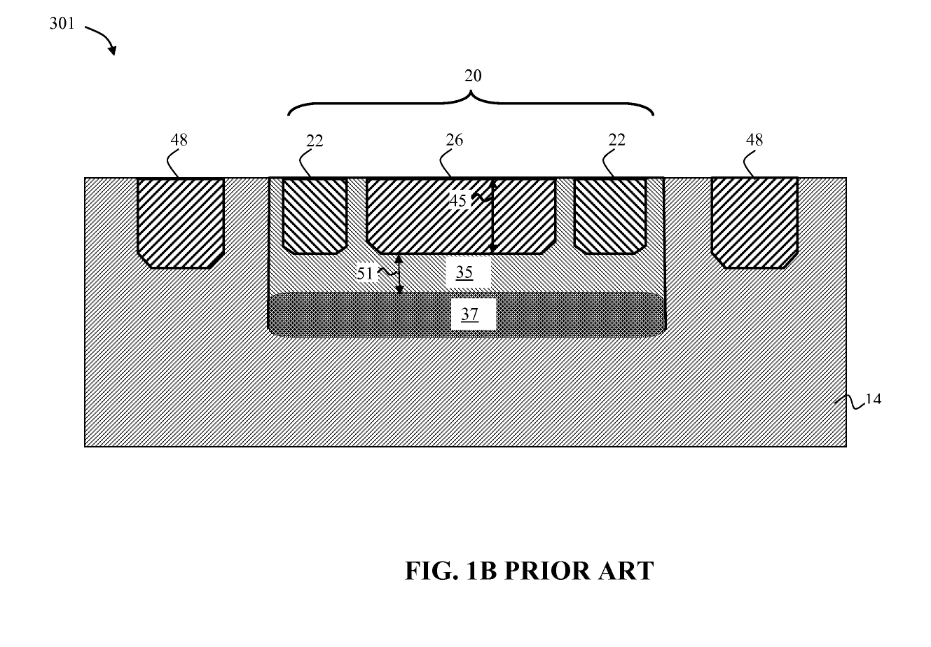

Referring to FIG. 2 in accordance with the present invention, first and second devices 10 and 11 of different operating voltage ratings are formed on a common semiconductor chip having a substrate 14, an epitaxial layer 16 grown on top of substrate 14. The epitaxial layer 16 is doped to substantially the same conductivity type and concentration as the substrate material 14. For VNPN devices 10 and 11 (N+ emitter and P+ base pickup not shown) shown in FIG. 2, substrate 14 and epitaxial layer 16 are p-type.

Low voltage device structure 20 of device 10 is formed in the substrate 14. Without showing the detail structure of device 10, a light doped and deep N well 35 is formed at the top portion of the epitaxial layer 16. Then a number of N-wells 22 and P-wells 26 are formed at the top portion of the deep N well 35 and a P-well 48 is formed in the top portion of the epitaxial layer 16 surrounding the deep N well 35 functioning as the isolation region for the device structure 20. P wells 26 and 48 are present in a greater doping concentration than are present in epitaxial layer 16 and substrate 14. Optionally, a buried layer of n-type dopant, (not shown) is formed at the bottom of the deep N well 35, under and proximity to the P-type well 26.

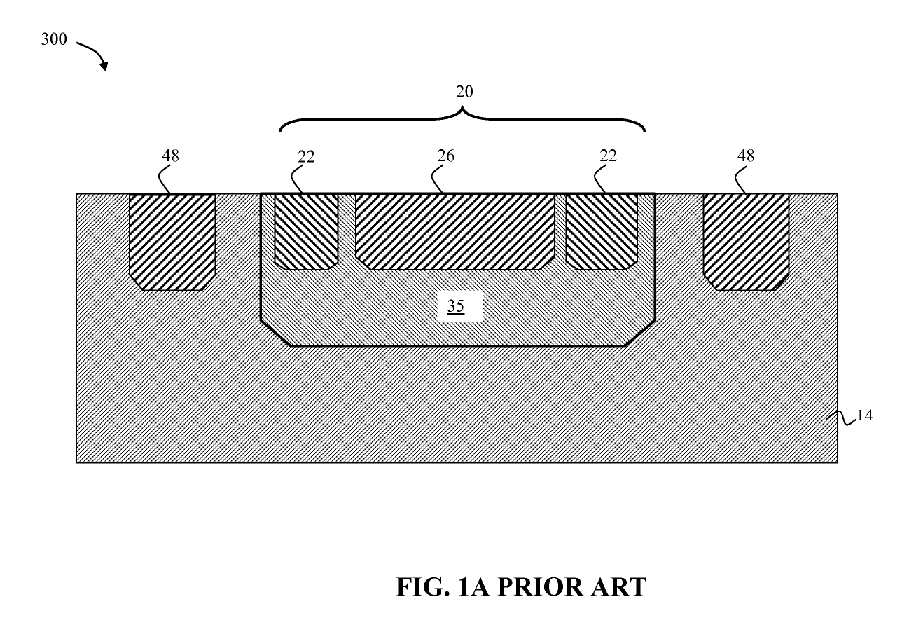

Device 10 is identical to the device 300 shown in FIG. 1A, except that device 10 has an additional epitaxial layer 16 formed on top of the substrate 14. Since the epitaxial layer 16 has the same doping concentration as the substrate 14, the performance of device 10 is identical to the device 300 as the epitaxial layer 16 can be considered as an extension of substrate 14. The existing manufacturing process and conditions of making device 300 can be transferred in whole as a process module of making device 10.

Also formed in substrate 14 and epitaxial layer 16 is device 11 in accordance with the present invention. Device 11 includes, formed into layer 16, a high voltage device structure 120. The device 11 includes lightly doped and deep N well 134 formed from the top surface of the epitaxial layer 16 and extending downward to a top portion of the substrate 14. The lightly doped and deep N well 134 can be formed by high energy implantation. A highly doped buried layer of n-type dopant, referred to as a deep buried layer 136, is optionally formed at the bottom of and surrounded by the deep N well 134, which extends between substrate 14 and epitaxial layer 16, for further increasing the maximum operating voltage of the device. The deep N well 134 and the buried layer 136 are formed as follow: first, a deep buried layer is implanted at the top surface of the substrate 14 including two different species, a highly doped first n-type portion, referred to as deep buried highly doped region 136, and a lightly doped second n-type portion, referred to as deep buried lightly doped region (not shown), with second portion surrounding the first portion 136; the epitaxial layer 16 is then grown on top of the substrate 14 followed by the formation of a lightly doped and deep N well at the top portion of the epitaxial layer 16. Preferably highly doped first n-type portion 136 is limited to a vicinity around the interface between the substrate material 14 and the p-epitaxial layer 16. A diffusion process is then carried out. For a given temperature, the second n-type dopant portion diffuses at a faster rate than the first n-type dopant portion. In the present example the dopant concentrated in first n-type dopant portion 136 is antimony or arsenic and the dopant concentrated in second n-type dopant portion is phosphorous. As such, the second n-type portion extends upward and converts portion of the P-type epitaxial layer 16 to lightly doped N type while the light doped and deep N well formed at the top portion of the epitaxial layer 16 is coming down from the surface of the epitaxial layer 16 and merges together with the second n-type portion forming the lightly doped and deep N well 134. Then, a number of N-wells 122 and P-wells 126 are provided in the top portion of the deep N well 134 and the P-well 148 is formed in the top portion of the epitaxial layer 16 surrounding the deep N well 134. P-type dopant of well 126 and 148 may be present in a greater concentration than are present in epitaxial layer 16 and substrate 14. P-wells 148 functions as an isolation ring for the device 120. Optionally, the isolation ring also includes a deep P buried region (not shown) overlapping with the P well 148 when the isolation ring needs to enclose the high voltage device 120 all the way around. It should be understood that isolation ring functions to isolate device 120 from adjacent devices, one of which is shown as active region 20 formed on substrate 14 and layer 16.

There are two breakdown voltages to consider with the device 11. First, a break down voltage of the buried region 134 and/or buried region 136 to substrate material 14 outside active region 120 can be controlled by doping concentrations of 134, 136 and 14 and doping profiles of 134 and 136. Second, a vertical breakdown voltage inside active device 120 is controlled by a vertical distance 51 between region 136 and region 126 and doping concentrations and profiles of regions 134, 136, and 126. In case the buried region 136 is omitted, the vertical breakdown voltage inside active device 120 is controlled by a vertical distance between the bottom of the region 126 and the bottom of the buried region 134 and doping concentrations and profiles of regions 134 and 126. The maximum operating voltage of device 120 is limited by the second vertical breakdown.

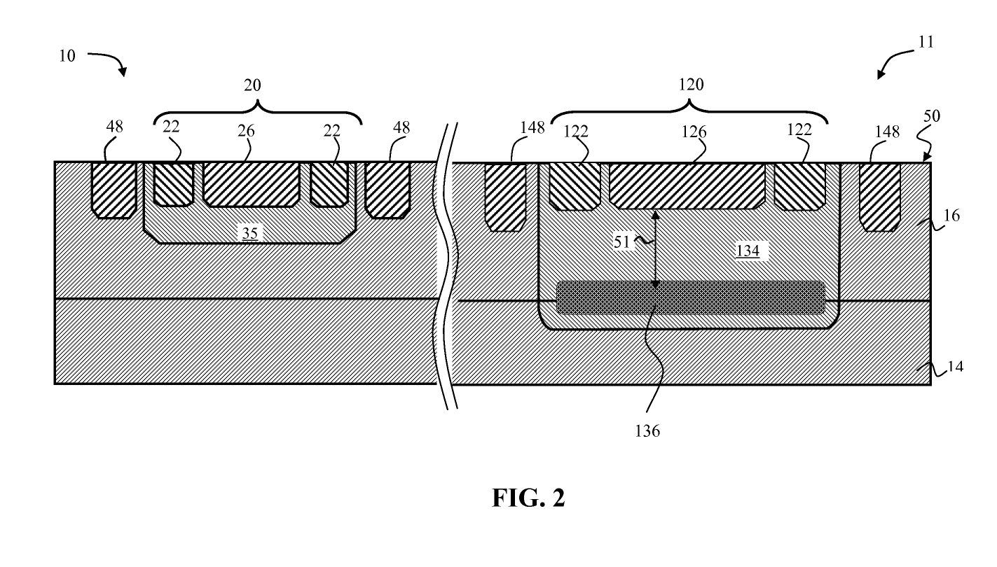

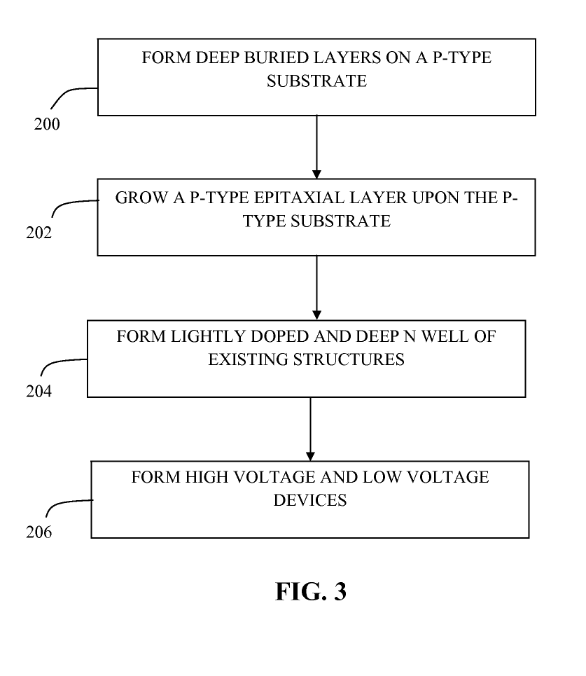

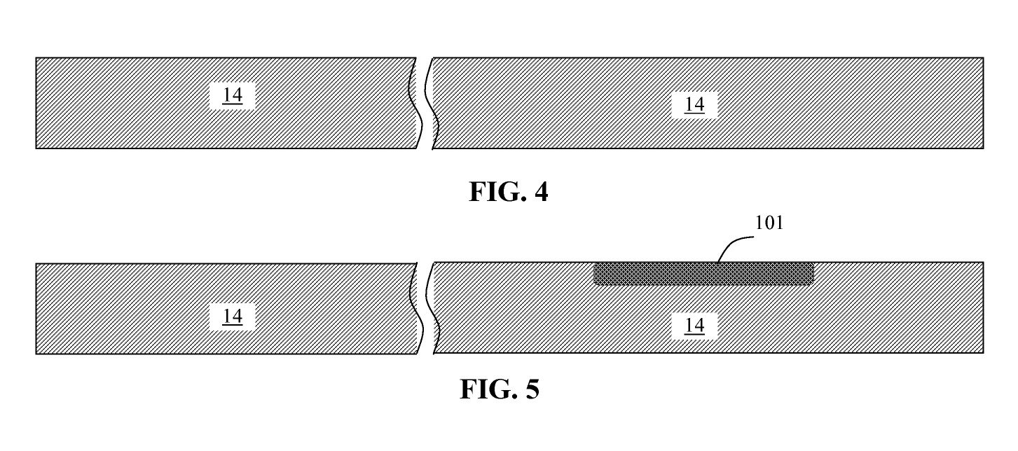

To fabricate devices 10 and 11 on a semiconductor chip a p-type substrate 14 is provided and deep buried region 101 is formed in the high voltage device area on top surface thereof the substrate 14 at step 200, shown in FIGS. 3-5. The dopant is implanted using well known implantation and masking processes to obtain a desired doping concentration. For making a high voltage device without the deep highly doped buried region 136, the deep buried region 101 only includes n-type dopant such as phosphorous. For making a high voltage device with the deep highly doped buried region 136, deep buried region 101 includes two different types of n-type dopant that have different rates of diffusion coefficient for a given temperature. In the current example, the first n-type dopant is antimony or arsenic and the second dopant is phosphorous, both of which are implanted into a same deep buried region 101 on substrate 14 with two step implantation. The low voltage device area is covered by photo resist to block the ion implant in this step.

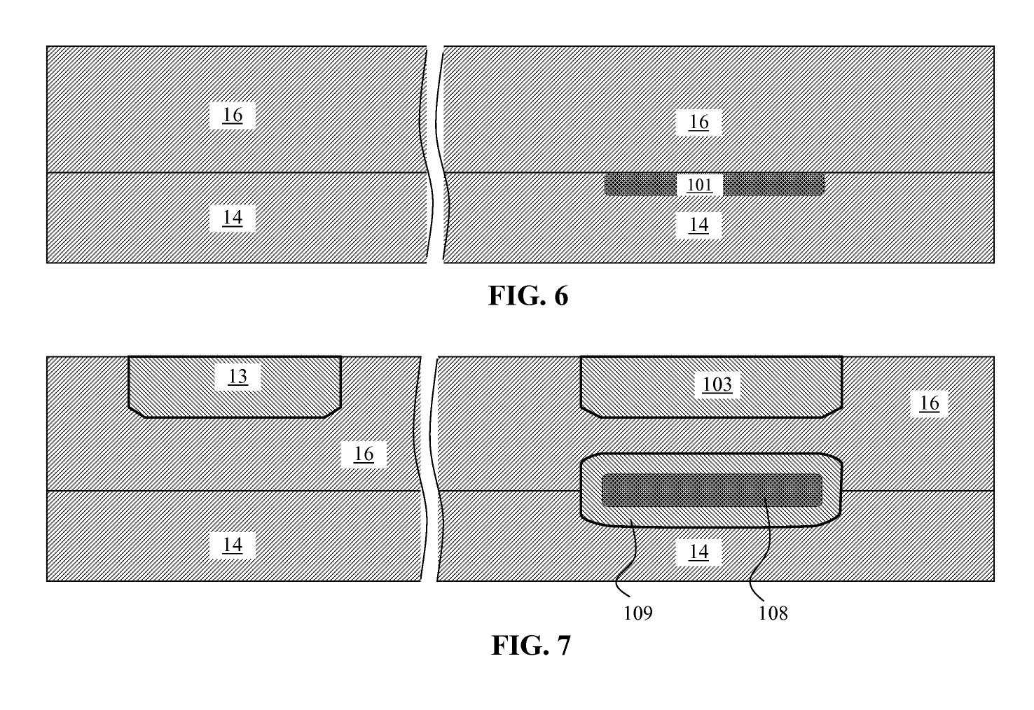

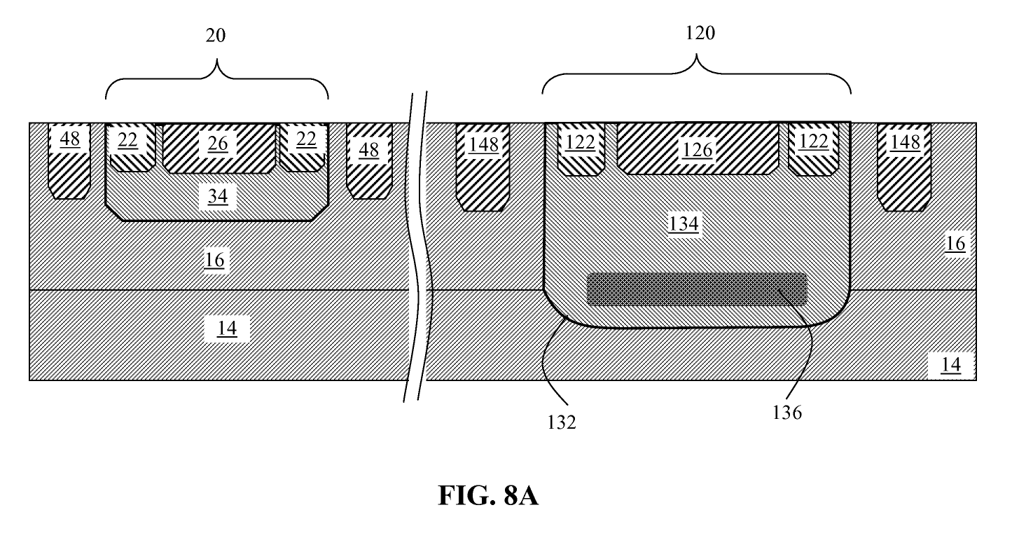

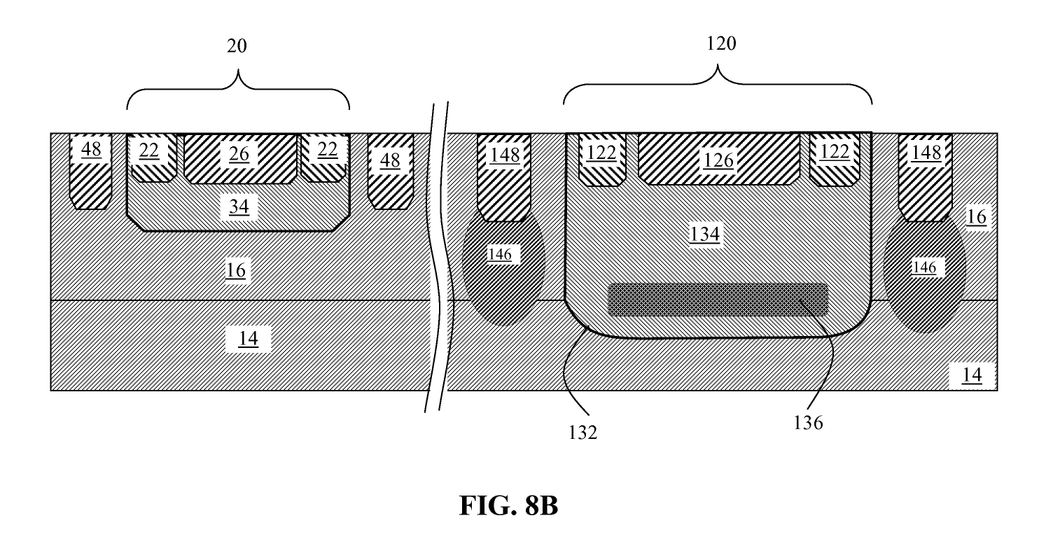

Referring to FIGS. 3 and 6, an epitaxial layer 16 is grown upon the substrate 14 at step 202 all over the areas. Epitaxial layer 16 preferably has the same p-type dopant and same doping concentration as substrate 14. At step 204, lightly doped and deep N wells 13 and 103, shown in FIG. 7, are formed on the top portion of the epitaxial layer 16. This is followed by a thermal anneal that results in the dopants in deep buried region 101, shown in FIG. 6, diffusing into both substrate and the first epitaxial layer 16, forming regions 108 and 109, shown in FIG. 8. Specifically, the difference in the diffusion coefficient between antimony and phosphorous, i.e. phosphorous diffuses faster than antimony, results in region 109 surrounding region 108, as discussed above. At step 206 and referring to FIG. 8A, p-type dopants are implanted into sub-regions 26, 126 into top portions of the deep N wells 34, 134 respectively and into sub-region 48, 148 into top portion of epitaxial layer 16, followed by implantation of n-type dopant into sub-regions 22, 122 into top portions of the deep N wells 34, 134 respectively. Then, thermal cycles are applied to drive the dopants into layer 16 sufficiently to provide the desired doping concentrations and profiles.

As such, the lightly doped phosphorous in region 109 extends upward to the P well 126 and converts portion of the P-type epitaxial layer 16 to lightly doped N type while the lightly doped and deep N well 103 formed at the top portion of the epitaxial layer 16 is coming down from the surface of the epitaxial layer 16 and merges together with the region 109 forming the lightly doped and deep N well 134. Isolation ring is formed by the P well 148. Optionally, as shown in FIG. 8B, the isolation ring can also include a deep P buried region 146 that expands and merges with the P well 148 when the diffusion step is carried out.

Referring to FIG. 2, the vertical distance 51 between region 136 (or bottom of 134, if 136 is omitted) and region 126 is controllable. As a result the device 120 has higher vertical breakdown voltage, hence, higher operating voltage than that of device 20.

Referring to FIGS. 3 and 8A, at step 206 active region of device 10 is formed by ion implantation into N-well regions 22 and P-well region 26 to configure the specific device structure of device 10 and active region of device 11 is formed by ion implantation into N-well regions 122 and P-well region 126 to configure specific device structure of device 11. It should be understood that although shown as a single step for ease of discussion, implantation of n-type and p-type dopants at step 206 occurs in multiple steps under conventional masking processes, ion implantations and high temperature drive-ins. As previously mentioned the proven process and conditions of making device 300 can be transferred in its entirety and implemented starting from step 204. It should be understood that both existing devices and newly added devices of the present invention having lower voltage rating and higher voltage rating, respectively, will co-exist on the same substrate material without affecting each other.

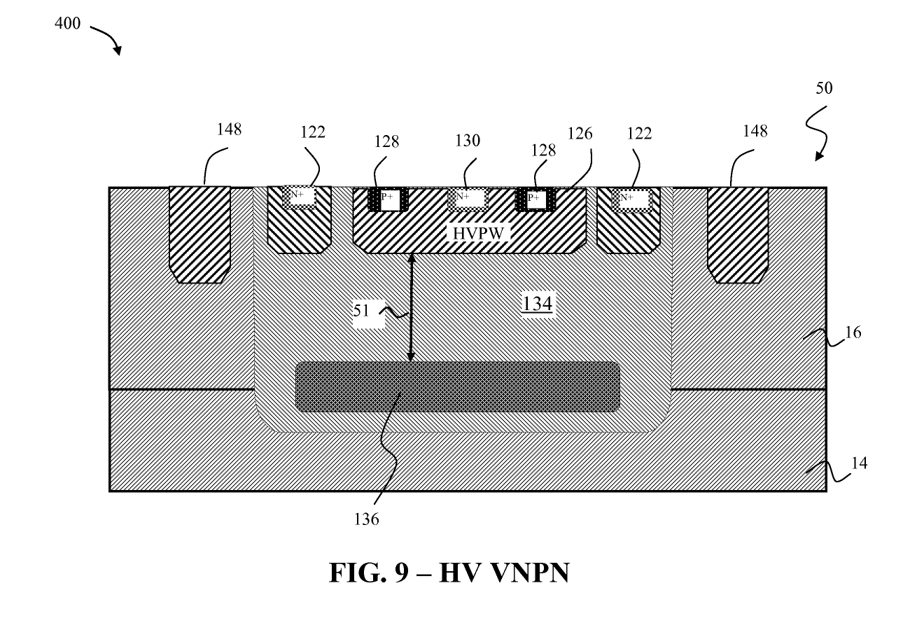

The process step 206 shown in FIG. 8A provides a semiconductor chip having a higher voltage device integrated with a lower voltage device. It is understood that device 10 or 11 can be a diode, a bipolar transistor, a MOSFET or other devices. It is further understood that any device combination can be integrated together without affecting each other using the techniques disclosed by this invention. FIG. 9 shows an embodiment of device 11 provided as a high voltage vertical NPN transistor (VNPN) 400 integrated with an existing low voltage device (not shown). Device 400 is the same as device 11 except that the active area of device 400 includes a highly doped N+ region 130 disposed in the high voltage P-well 126. The highly doped N+ region 130, the P-well 126 and the deep buried N region 134 below the P-well 126 configures a vertical NPN with N+ region 130 provided as the emitter, P-Well 126 provided as the base and the N regions below the HVPW 126 provided as the collector. The P+ regions 128 disposed in HVPW 126 provide contact pickups to the base while the N regions 122 disposed in top portion of the epitaxial layer 16 outside of the HVPW 126 provide contact pickups to the collector. The base and collector contact pickups may be formed as ring shapes in layout. The distance 51 between a bottom of the base region 126 and a top of the deep buried highly doped region 136 (or bottom of 134, if 136 is omitted) controls the vertical breakdown of the NPN transistor therefore limits the operating voltage of the NPN transistor 400.

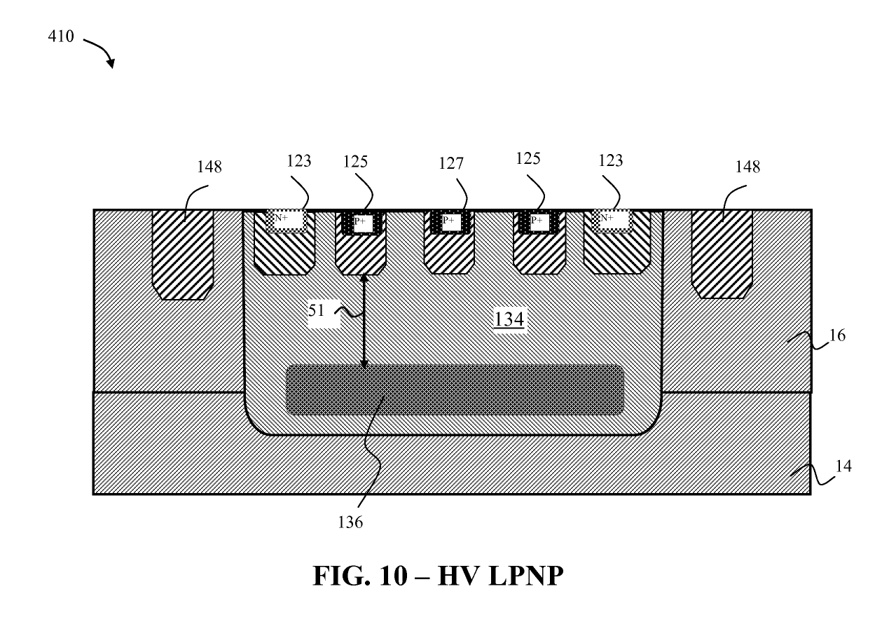

FIG. 10 shows an alternate embodiment of device 11 provided as a high voltage lateral PNP transistor (LPNP) 410 integrated with an existing low voltage device (not shown). Device 410 is the same as device 11 except that the active area of device 410 is configured as a lateral PNP including a P region 127 provided as the emitter, a P ring 125 provided as the collector encircling the central P emitter region 127, and a N ring 123 provided as base contact pickup encircling the collector P ring 125 and the emitter P region 127. The base region includes the deep N well 134 and the deep buried highly doped region 136 enclosed within a lightly doped deep N well 134. The distance 51 between a bottom of the P collector region 125 and a top of the deep buried highly doped region 136 (or bottom of 134, if 136 is omitted) controls the vertical breakdown of the PNP transistor therefore limits the operating voltage of the PNP transistor 410.

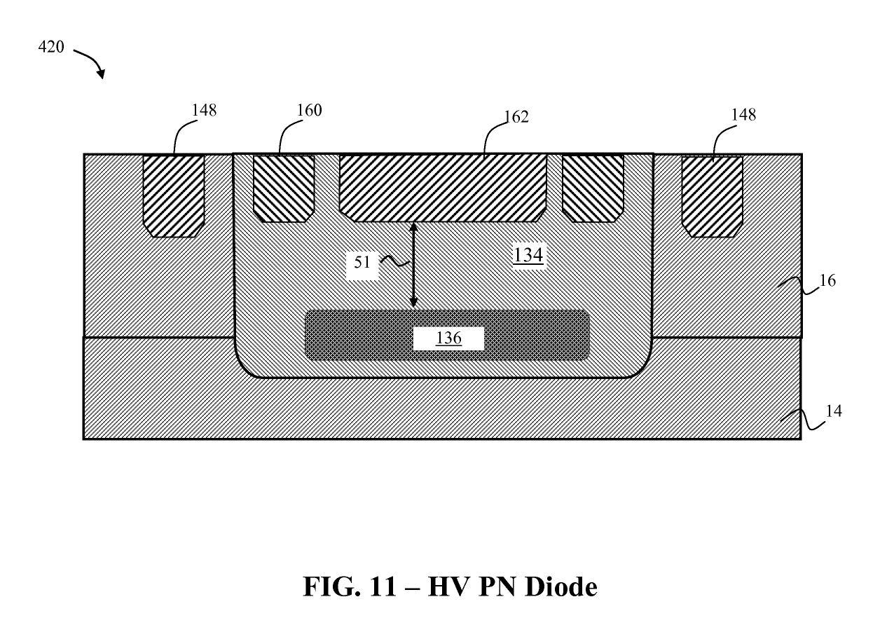

FIG. 11 shows an alternate embodiment of device 11 provided as a high voltage PN diode 420 integrated with an existing low voltage device (not shown). Device 420 is the same as device 11 except that the active area of device 420 is configured as a PN diode including a P region 162 provided as the anode and an N region 160 as contact pickup for the cathode that includes a portion of the deep N well 134. The distance 51 between a bottom of the anode P region 162 and a top of the deep buried highly doped region 136 (or bottom of 134, if 136 is omitted) controls the vertical breakdown of the diode therefore limits the operating voltage of the diode 420.

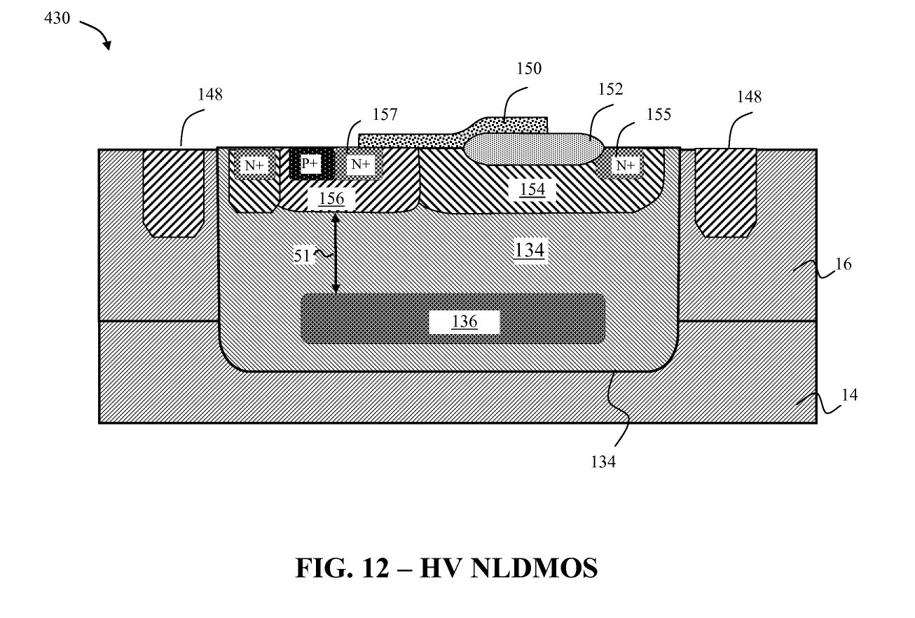

FIG. 12 shows an alternate embodiment of device 11 provided as a high voltage N-channel Lateral DMOS (LDMOS) integrated with an existing low voltage device (not shown). Device 430 is the same as device 11 except that the active area of device 430 is configured as a N-channel LDMOS that includes a N+ source region 157 disposed in P-well 156 and a N+ drain contact pickup region 155 disposed in N-well 154. The P-well 156 is provided as the body and an N region including the N-well 154 and the deep N well 134 is provided as the drain. A field oxide 152 is formed on a top portion of the N-well 154 right next to the drain contact pickup region 155 and an insulated gate 150 disposed on top of the P-well 156 and the N-well 154 extends from overlapping a portion of the source region 157 to overlapping a portion of the field oxide 152. The distance 51 between a bottom of the P body region 156 and a top of the deep buried highly doped region 136 (or bottom of 134, if 136 is omitted) controls the vertical breakdown of the N-channel LDMOS therefore limits the operating voltage of the LDMOS 430.

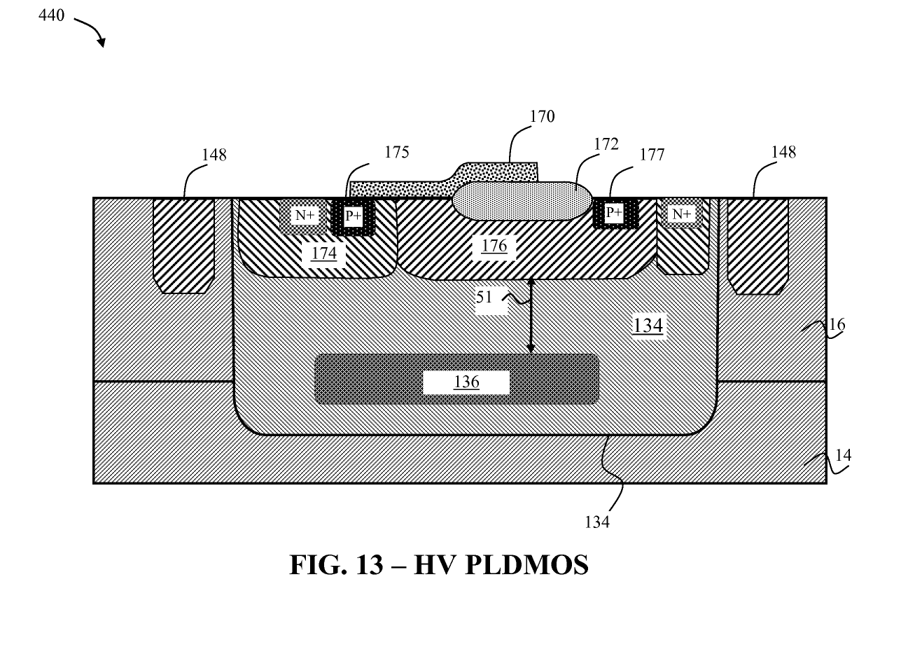

A P-channel LDMOS 440 can be formed in a same way as shown in FIG. 13, except that the P+ source region 175 is now disposed in N-well 174 provided as the body and P+ drain contact pickup 177 is now disposed in P-well 176 provided as the drain. The distance 51 between a bottom of the P drain region 176 and a top of the deep buried highly doped region 136 (or bottom of 134, if 136 is omitted) controls the vertical breakdown of the P-channel LDMOS therefore limits the operating voltage of the LDMOS 440.

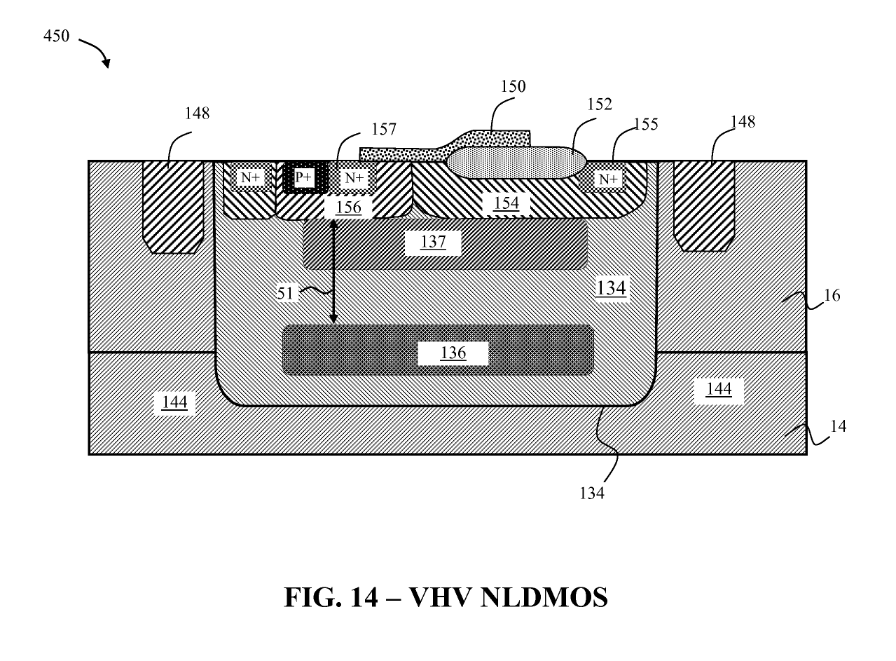

FIG. 14 shows an alternate embodiment of device 11 provided as a very high voltage N-channel Lateral DMOS (LDMOS) integrated with an existing low voltage device (not shown). Device 450 is the same as device 430 except that a RESURF region 137 is provided as a deep P-well (DPW) within a top portion of the deep N well 134. The DPW region 137 depletes under reverse bias therefore functions as triple RESURF, thus, improves performance of previously described device 430. The DPW region 137 can be formed by ion implantation from the top surface of the epitaxial layer 16 using a high energy implanter before forming Pwell 156 and Nwell 154. Preferably the floating DPW region 137 is adjacent to P body region 156. The distance 51 between a bottom of the P body region 156 and a top of the deep buried highly doped region 136 (or bottom of 134, if 136 is omitted) controls the vertical breakdown of the N-channel LDMOS therefore limits the operating voltage of the LDMOS 450.

It should be understood that the foregoing description is merely an example of the invention and that modifications may be made thereto without departing from the spirit and scope of the invention and should not be construed as limiting the scope of the invention. The scope of the invention, therefore, should be determined with respect to the appended claims, including the full scope of equivalents thereof.

1. A semiconductor chip comprising a first device and a second device disposed thereon, said semiconductor chip further comprising:
a substrate layer of a first conductivity type;
an epitaxial layer of the first conductivity type on a top surface of the substrate layer;
a deep and lightly doped well of the second conductivity type formed from the top surface of the epitaxial layer and extending to a top portion of the substrate layer in an area for the first device;
a lightly doped well of the second conductivity type formed from a top surface of the epitaxial layer to a depth about half of the thickness of the epitaxial layer in an area for the second device; and
a first doped well of the first conductivity type formed at a top portion of the deep and lightly doped well in the area for the first device and a second doped well of the first conductivity type formed at a top portion of the lightly doped well in the area for the second device.

2. The semiconductor chip as recited in claim 1 wherein the dopant concentration of the epitaxial layer being substantially the same as the substrate layer.

3. The semiconductor chip as recited in claim 2 further comprising a deep buried highly doped region of a second conductivity type opposite to the first conductivity type at the bottom of the lightly doped well in an area for the second device.

4. The semiconductor chip as recited in claim 2 further comprising a deep buried highly doped region of a second conductivity type opposite to the first conductivity type at an interface between the substrate layer and the epitaxial layer surrounding by the deep and lightly doped well in an area for the first device.

5. The semiconductor chip as recited in claim 2 further comprising isolation regions surrounding active areas of the first device and second device.

6. The semiconductor chip as recited in claim 1 wherein a distance between a bottom of the first doped well of the first conductivity type and the deep buried highly doped implant region of the second conductivity type control an operation voltage of the first device.

7. The semiconductor chip as recited in claim 1 wherein the first device comprising a NPN bipolar transistor and the first doped well being configured as a base of the NPN bipolar transistor.

8. The semiconductor chip as recited in claim 1 wherein the first device comprising a PNP bipolar transistor and the first doped well being configured as a collector of the PNP bipolar transistor.

9. The semiconductor chip as recited in claim 1 wherein the first device comprising a PN diode and the first doped well being configured as an anode of the PN diode.

10. The semiconductor chip as recited in claim 1 wherein the first device comprising a N channel DMOS transistor and the first doped well being configured as a base of the DMOS transistor.

11. The semiconductor chip as recited in claim 10 wherein the N channel DMOS transistor further comprising a buried doped region of the first conductivity type disposed above the deep buried highly doped region of the second conductivity type configured as a RESURF layer.

12. The semiconductor chip as recited in claim 1 wherein the first device comprising a P channel DMOS transistor and the first doped well being configured as a drain of the DMOS transistor.

13. The semiconductor chip as recited in claim 1 further comprising isolation regions surrounding an active area of the first device.

14. The semiconductor chip as recited in claim 1 wherein the dopant concentration of the first epitaxial layer being substantially the same as the substrate.

15. The semiconductor chip as recited in claim 14 further comprising a second device disposed in a second device area thereon, said second device area further comprising a lightly doped well of the second conductivity formed from a top surface of the epitaxial layer to a depth about half of the thickness of the epitaxial layer.

16. The semiconductor chip as recited in claim 15 further comprising a highly doped buried implant region of the second conductivity type formed at the bottom of the lightly doped well and surrounded by the lightly doped well and a second doped well of the first conductivity type formed at t top portion of the lightly doped well and above the highly doped buried implant region.

17. The semiconductor chip as recited in claim 1 wherein the first device having an operation voltage higher than the second device.

18. A semiconductor chip comprising a high voltage device and a low voltage device disposed thereon, said semiconductor chip further comprising:
a substrate layer of a first conductivity type;
an epitaxial layer of the first conductivity type on a top surface of the substrate layer, with the dopant concentration of the epitaxial layer being substantially the same as the substrate;
a deep and lightly doped well of the second conductivity type formed from the top surface of the epitaxial layer and extending to a top portion of the substrate layer in an area for the high voltage device;
a lightly doped well of the second conductivity type formed from a top surface of the epitaxial layer to a depth about half of the thickness of the epitaxial layer in an area for the low voltage device;
a first doped well of the first conductivity type extending formed in a top portion of the deep and lightly doped well in an area for the high voltage device and a second doped well of the first conductivity type formed in a top portion of the lightly doped well in an area for the low voltage device; and
isolation regions surrounding active areas of the high voltage device and said low voltage device.
